(19) United States
(12) Patent Application Publication
(10) Pub. No.: US 2018/0141311 A1
(43) Pub. Date: May 24, 2018

(54) DOUBLE-SIDED METAL-CLAD LAMINATE BOARD AND METHOD FOR MANUFACTURING SAME

(71) Applicant: Panasonic Intellectual Property Management Co. Ltd., Osaka (JP)

(72) Inventors: TAKAYOSHI OZEKI, Osaka (JP); YOHSUKE ISHIKAWA, Mie (JP); YOSHIAKI ESAKI, Osaka (JP)

(21) Appl. No.: 15/537,552

(22) PCT Filed: Jan. 28, 2016
(86) PCT No.: PCT/JP2016/000419

§ 371 Date: Jun. 19, 2017

(30) Foreign Application Priority Data
Jan. 30, 2015 (JP) 2015-017684

(51) Int. Cl. B32B 15/088; C08G 18/34; C08G 73/14; H05K 1/03

(52) U.S. Cl. CPC B32B 15/088; C08G 18/34; B32B 15/20; H05K 1/03; C08G 73/14

(57) ABSTRACT

A double-sided metal-clad laminate board includes a first metal layer; a second metal layer, and an insulating layer intervening between the first metal layer and the second metal layer. And the insulating layer is in direct contact with the first metal layer and the second metal layer. The insulating layer is a single layer containing a polyamide-imide resin having at least one of a first constituent unit represented by structural formula (1) and a second constituent unit represented by structural formula (2):

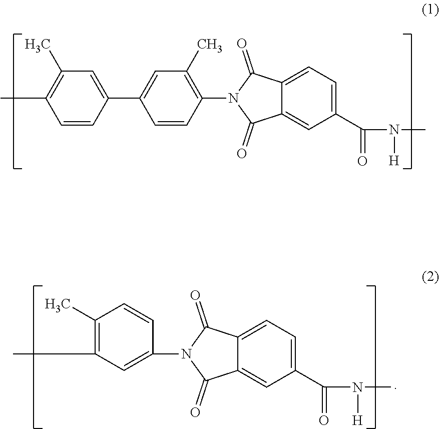

### TECHNICAL FIELD

The present disclosure relates to a double-sided metal-clad laminate board and a method for manufacturing the same.

### BACKGROUND

In order to improve reliability of a flexible printed wiring board and the like, an insulating layer of a double-sided metal-clad laminate board is required to have high heat resistance. Therefore, a double-sided metal-clad laminate board having an insulating layer formed from a highly heat resistant polyimide has been conventionally used as a material for a flexible printed wiring board and the like.

However, adhesiveness of the highly heat resistant polyimide to metal is low. Therefore, in order to bond between a metal layer and an insulating layer formed from a highly heat resistant polyimide, a thermoplastic adhesive such as thermoplastic polyimide has been conventionally used (refer to PTL l).

### CITATION LIST

### Patent Literature

PTL 1: Unexamined Japanese Patent Publication No. 2001-270033

### SUMMARY

A double-sided metal-clad laminate board according to the present disclosure includes a first metal layer, a second metal layer, and an insulating layer intervening between the first metal layer and the second metal layer. The insulating layer is in direct contact with each of the first metal layer and the second metal layer. The insulating layer is a single layer containing a polyamide-imide resin including at least one of a first constituent unit represented by structural formula (1) below and a second constituent unit represented by structural formula (2) below.

In a first method for manufacturing a double-sided metal-clad laminate board according to the present disclosure, first, a liquid composition containing a polyamide-imide resin and a solvent are applied to one surface of a first metal foil. The polyamide-imide resin includes at least one of a first constituent unit represented by structural formula (1) below and a second constituent unit represented by structural formula (2) below. Next, a resin layer is formed on the first metal foil by heating the liquid composition applied to the first metal foil such that a maximum temperature is from 200° C. to 300° C., both inclusive. Next, an insulating layer is formed by heating the resin layer, in a state that the resin layer and a second metal foil are laminated, such that a maximum temperature is from 300° C. to 350° C., both inclusive.

In a second method for manufacturing a double-sided metal-clad laminate board according to the present disclosure, first, a liquid composition containing a polyamide-imide resin and a solvent are applied to one surface of a first metal foil. The polyamide-imide resin includes at least one of a first constituent unit represented by structural formula (1) below and a second constituent unit represented by structural formula (2) below. Next, a first resin layer is formed on the first metal foil by heating the liquid composition applied to the first metal foil such that a maximum temperature is 200° C. or more and less than 300° C. Next, the liquid composition containing a polyamide-imide resin and a solvent are applied to one surface of a second metal foil. The polyamide-imide resin includes at least one of a first constituent unit represented by structural formula (1) below and a second constituent unit represented by structural formula (2) below. Next, a second resin layer is formed on the second metal foil by heating the liquid composition applied to the second metal foil such that a maximum temperature is 200° C. or more and less than 300° C. Then, an insulating layer is formed by heating the first resin layer and the second resin layer, in a state that the first resin layer and the second resin layer are laminated, such that a maximum temperature is from 300° C. to 350° C., both inclusive.

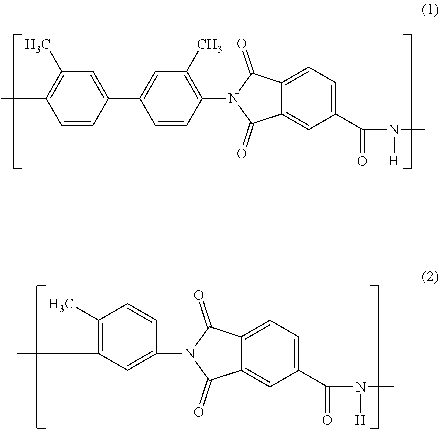

According to the present disclosure, a double-sided metal-clad laminate board that includes an insulating layer having high flexibility and high heat resistance can be obtained.

### BRIEF DESCRIPTION OF DRAWINGS

FIG. 1A is a cross-sectional view illustrating a step of forming a resin layer on a first metal foil, in a method for manufacturing a double-sided metal-clad laminate board according to an exemplary embodiment of the present disclosure.

FIG. 1B is a cross-sectional view illustrating a step of disposing a second metal foil on the resin layer, after the step of FIG. 1A.

FIG. 1C is a cross-sectional view illustrating the double-sided metal-clad laminate board according to the exemplary embodiment of the present disclosure.

FIG. 2A is a cross-sectional view illustrating a step of forming a first resin layer on a first metal foil, and also forming a second resin layer on a second metal foil, in another method for manufacturing a double-sided metal-clad laminate board according to an exemplary embodiment of the present disclosure.

FIG. 2B is a cross-sectional view illustrating a step of sticking the first resin layer and the second resin layer, after the step of FIG. 2A.

FIG. 2C is a cross-sectional view illustrating the double-sided metal-clad laminate board according to the exemplary embodiment of the present disclosure.

FIG. 3A is a cross-sectional view illustrating a step of preparing a double-sided metal-clad laminate board, in a method for manufacturing a multilayer flexible printed wiring board according to an exemplary embodiment of the present disclosure.

FIG. 3B is a cross-sectional view illustrating a step of obtaining a core material from a double-sided metal-clad laminate board, after the step of FIG. 3A.

FIG. 3C is a cross-sectional view illustrating a step of preparing a metal-clad substrate, after the step of FIG. 3R.

FIG. 3D is a cross-sectional view illustrating a step of obtaining a laminate, after the step of FIG. 3C.

FIG. 3E is a cross-sectional view illustrating the multilayer flexible printed wiring board according to the exemplary embodiment of the present disclosure.

FIG. 4A is a cross-sectional view illustrating a step of preparing a resin sheet for a core material, in a method for manufacturing a flex-rigid printed wiring board according to an exemplary embodiment of the present disclosure.

FIG. 4B is a cross-sectional view illustrating a step of disposing the resin sheet on the core material, and also providing a third insulating layer in the resin sheet, after the step of FIG. 4A.

FIG. 4C is a cross-sectional view illustrating the flex-rigid printed wiring board according to the exemplary embodiment of the present disclosure.

### DESCRIPTION OF EMBODIMENT

Prior to descriptions of exemplary embodiments of the present disclosure, problems in a conventional printed wiring board will be described.

An adhesive layer used in a conventional printed wiring board described in PTL 1 can bond between a metal layer and an insulating layer formed from a highly heat resistant polyimide. However, a thermoplastic adhesive becomes a cause of lowering heat resistance of the insulating layer.

Considering the above problems, the present disclosure provides a double-sided metal-clad laminate board that includes an insulating layer having high flexibility and high heat resistance, and a method for manufacturing the same.

Hereinafter, exemplary embodiments of the present disclosure will be described. However, the present disclosure is not limited thereto.

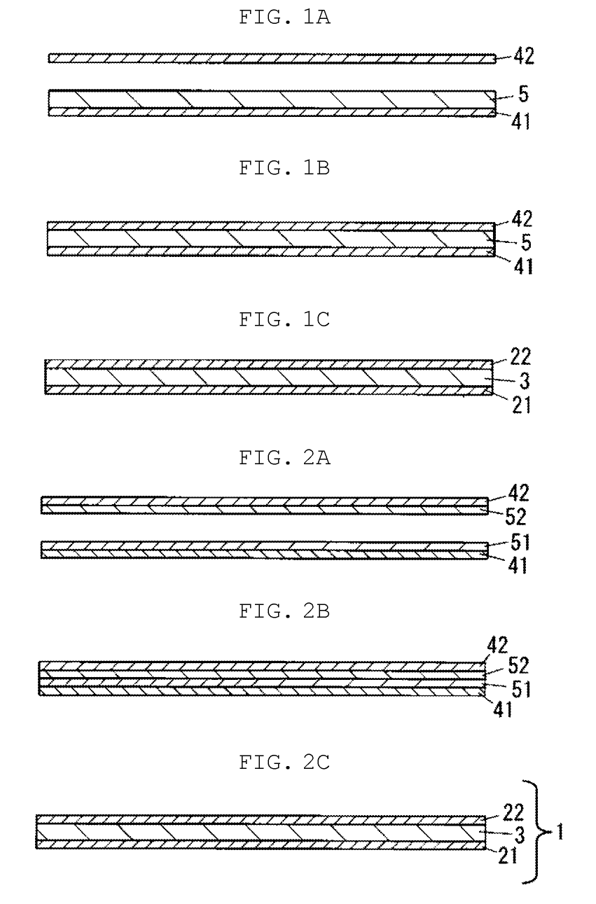

FIG. 1C shows double-sided metal-clad laminate board 1 according to the present exemplary embodiment. Hereinafter, double-sided metal-clad laminate board 1 is referred as laminate board 1. Laminate board 1 includes first metal layer 21, second metal layer 22, and insulating layer 3. Hereinafter, first metal layer 21 is referred as metal layer 21, and second metal layer 22 is described as metal layer 22. Insulating layer 3 intervenes between metal layer 21 and metal layer 22, and is in direct contact with metal layer 21 and metal layer 22. Insulating layer 3 contains a polyamide-imide resin that includes at least one of a first constituent unit represented by structural formula (1) below and a second constituent unit represented by structural formula (2) below. Insulating layer 3 is a single layer. That is, no discontinuous change of the composition exists in insulating layer 3. Hereinafter, the first constituent unit is referred as constituent unit X, and the second constituent unit is referred as constituent unit Y.

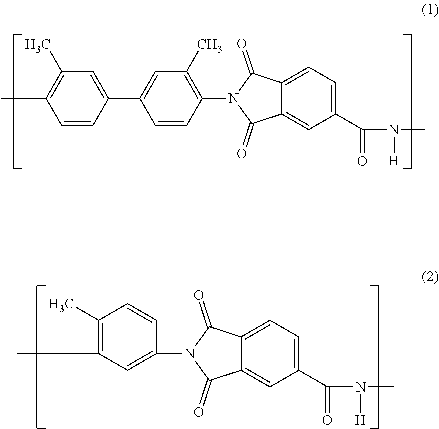

In laminate board 1, insulating layer 3 contains a polyamide-imide resin as described above, and insulating layer 3 is a single layer. Due to the polyamide-imide resin, insulating layer 3 is provided with high flexibility and high heat resistance. Also, insulating layer 3 is a single layer, thus flexibility and heat resistance of insulating layer 3 are not inhibited by adhesives and the like. Therefore, insulating layer 3 has high flexibility, and also has high heat resistance.

Laminate board 1 having the above constitution has not been conventionally obtained. This is because adhesion between metal and insulating layer 3 containing the polyamide-imide resin is low. On the other hand, laminate board 1 has a constitution that insulating layer 3 which contains the polyamide-imide resin as described above and which is a single layer is in direct, contact with metal layer 21 and metal layer 22.

Laminate board 1 is manufactured, for example, by a first method as illustrated in FIGS. 1A to 1C. In the first method, first, a liquid composition containing a poly amide-imide resin and a solvent are applied to one surface of first metal foil 41. Then, the liquid composition is heated such that the maximum temperature is 200° C. or more and less than 300° C., so that resin layer 5 is formed on first metal foil 41, as illustrated in FIG. 1A. Hereinafter, first metal foil 41 is referred as metal foil 41. Next, second metal foil 42 is laminated on resin layer 5, as illustrated in FIG. IB. Hereinafter, second metal foil 42 is referred as metal foil 42. Then, in a state that resin layer 5 and metal foil 42 are laminated, resin layer 5 is heated at a temperature from 300° C. to 350° C., both inclusive. By heating resin layer 5, resin layer 5 is cured, and insulating layer 3 is bonded to metal foil 41 and metal foil 42. Resin layer 5 is cured, so that insulating layer 3 is formed. In addition, metal foil 41 constitutes metal layer 21, and metal foil 42 constitutes metal layer 22.

According to the above method, laminate board 1 as illustrated in FIG. 1C is obtained.

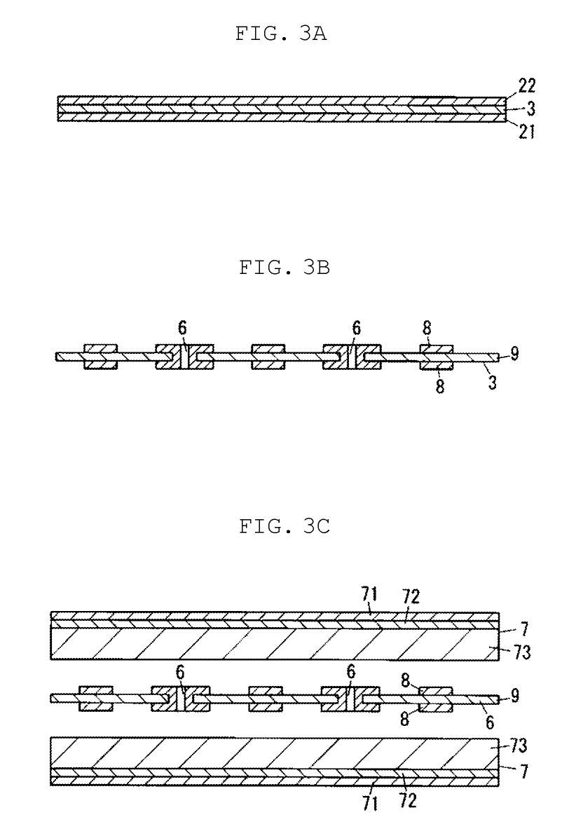

Laminate board 1 may be manufactured by a second method shown below, as illustrated in FIG. 2A to FIG. 2C. in the second method, first, a liquid composition containing the polyamide-imide resin and a solvent are applied to one surface of metal foil 41. Then, the liquid composition is heated such that the maximum temperature is 200° C. or more and less than 300° C., so that first resin layer 51 is formed on metal foil 41. Hereinafter, first resin layer 51 is referred as resin layer 51. Also, the liquid composition containing the polyamide-imide resin and a solvent are applied to one surface of metal foil 42. Then, the liquid composition is heated at a temperature of 200° C. or more and less than 300° C., so that second resin layer 52 is formed on metal foil 42 (refer to FIG. 2A). Hereinafter, second resin layer 52 is referred as resin layer 52. Next, as illustrated in FIG 2R, in a state that resin layer 51 and resin layer 52 are laminated, resin layers 51, 52 are heated at a temperature from 300° C. to 350° C., both inclusive. By heating, resin layer 51 and resin layer 52 are bonded and integrated, and integrated resin layers 51, 52 are cured. Resin layers 51, 52 are cured, so that insulating layer 3 is formed. In addition, this insulating layer 3 is bonded to metal foil 41 and metal foil 42. Also, metal foils 41, 42 constitute metal layers 21, 22, respectively, in the same manner as in the first method (refer to FIG. 2C).

According to the above methods, laminate board 1 is obtained.

Double-sided metal-clad laminate board 1 and a method for manufacturing the same will be described in more detail.

First, metal foils 41, 42 are prepared. Each of materials of metal foils 41, 42 is not particularly limited. Examples of metal foils 41, 42 include a copper foil. A thickness of each of metal foils 41, 42 is, for example, preferably from 3 μm to 70 μm, both inclusive. Also, a thickness of each of metal foils 41, 42 may be from 1 μm to 5 μm, both inclusive, and may further be from 1 μm to 3 μm, both inclusive.

The polyamide-imide resin contained in insulating layer 3 includes at least one of constituent unit X and constituent unit Y, as described above. By this constitution, the polyamide-imide resin has a high glass transition temperature. Therefore, insulating layer 3 has high heat resistance. Furthermore, insulating layer 3 is provided with excellent flexibility. Also, insulating layer 3 can be more firmly bonded to metal layers 21, 22.

In particular, the polyamide-imide resin may include both constituent unit X and constituent unit Y. By this constitution, adhesion between insulating layer 3 and metal layers 21, 22 is significantly increased, and heat resistance of insulating layer 3 is significantly increased.

When the polyamide-imide resin includes both constituent unit X and constituent unit Y, the proportion of constituent unit Y is preferably from 5% by mol to 35% by mol, both inclusive, relative to the total of constituent unit X and constituent unit Y in the polyamide-imide resin. When the proportion of constituent unit Y is 35% by mol or less relative to the total, it means that the proportion of constituent unit X is 65% by mol or more relative to the total. By this molar ratio, the heat resistance of insulating layer 3 is significantly improved. Also, when the proportion of constituent unit Y is 5% by mol or more relative to the total, it means that the proportion of constituent unit X is 95% by mol or less relative to the total. By this molar ratio, insulating layer 3 can be significantly firmly bonded to metal layers 21, 22. In addition, when constituent unit Y is 5% by mol or more relative to the total, the polyamide-imide resin is more easily dissolved in the solvent during preparation of the liquid composition used for manufacturing laminate board 1. Therefore, molding defects during formation of insulating layer 3 is suppressed. It is also preferred that the proportion of constituent unit Y is 10% by mol or more relative to the total. In particular, it is preferred that the proportion of constituent unit Y is 30% by mol or less, and more preferred that the proportion of constituent unit Y is within the range from 10% by mol to 30% by mol, both inclusive.

The polyamide-imide resin may be constituted by only constituent units X, Y. In addition, a constituent unit other than constituent units X, Y may be included in the polyamide-imide resin. The constituent unit other than constituent units X, Y is referred to as an additional constituent unit, and is hereinafter referred as constituent unit Z. It is preferred that the proportion of constituent unit Z relative to the total constituent units in the polyamide-imide resin is 20% by mol or less, and is further preferred that the proportion is 10% by mol or less.

Constituent unit Z has, for example, a structure represented by structural formula (3) below.

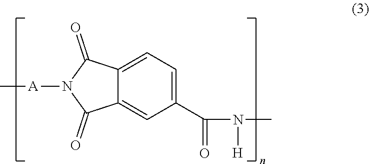

A in structural formula (3) is an aromatic residue. The structure of A is not particularly limited. Examples of the structure of A include structures shown below.

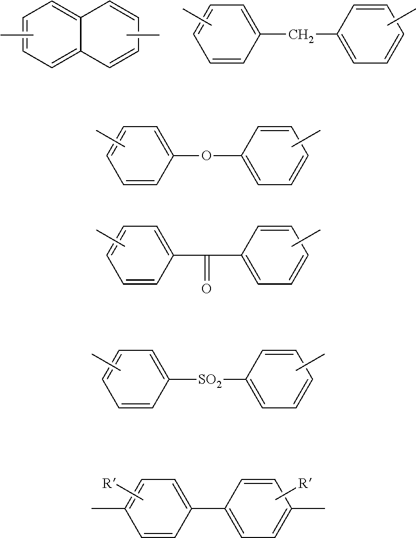

R¹ and R² in the above structural formula are selected from hydrogen, and alkyl groups and allyl groups having 1 to 3 carbon atoms. The same structures as constituent units X, Y are excluded from constituent unit Z.

Examples of a method for synthesizing the polyamide-imide resin include isocyanate method and amine method. Examples of the amine method include acid chloride method, low temperature solution polymerization method, and room temperature solution polymerization method. In particular, it is preferred to use the isocyanate method since a polymerization liquid can be applied as it is.

When a poly amide-imide resin is synthesized by the isocyanate method, for example, trimellitic acid and an aromatic diisocyanate are added to an organic solvent to prepare a reactive solution. In place of the trimellitic acid, a derivative such as an anhydride or halide of the trimellitic acid can be also used. The aromatic diisocyanate is used for introducing an aromatic residue. A catalyst may be further added to the reactive solution as necessary. This reactive solution is subjected to reaction under heating, so that the poly amide-imide resin can be synthesized. As reaction conditions, the temperature is set to be from 10° C. to 200° C., both inclusive, and the time is set to be from 1 hour to 24 hours, both inclusive.

As the aromatic diisocyanate, for example, 4,4′-diisocyanato-3,3′-dimethylbiphenyl and 2,4-diisocyanatotoluene are used. In this case, by adjusting the molar ratio of 4,4′-diisocyanato-3,3′-dimethylbiphenyl and 2,4-diisocyanatotoluene, the molar ratio of constituent units X, Y in the polyamide-imide resin can be adjusted. Also, as the aromatic diisocyanate, a component other than 4,4′-diisocyanato-3,3′-dimethylbiphenyl and 2,4-diisocyanatotoluene is further contained, so that it is also possible to introduce constituent unit Z to the polyamide-imide resin.

Specific examples of the polyamide-imide resin include item number HR-16NN manufactured by TOYOBO CO., LTD.

The organic solvent used in preparation of the reactive solution contains, for example, one or more kinds of components selected from the group consisting of N-methyl-2-pyrrolidone, N,N-dimethylformamide, N,N-dimethylacetamide, 1,3-dimethyl-2-imidazolidinone, tetramethylurea, sulfolane, dimethyl sulfoxide, γ-butyrolactone, cyclohexanone, and cyclopentanone. Alternatively, the organic solvent further contains one or more kinds of components selected from the group consisting of hydrocarbon-based organic solvents such as toluene and xylene, ether-based organic solvents such as diglyme, triglyme and tetrahydrofuran, and ketone-based organic solvents such as methyl ethyl ketone and methyl isobutyl ketone.

Examples of the catalyst include tertiary amines, alkali metal compounds, alkaline earth metal compounds, and the like.

When a polyamide-imide resin is synthesized by the amine method, for example, trimellitic acid and an aromatic diamine are added to an organic solvent to prepare a reactive solution. In place of the trimellitic acid, a derivative such as an anhydride or halide of the trimellitic acid can be also used. The aromatic diamine is used for introducing an aromatic residue. A catalyst may be further added to the reactive solution as necessary. This reactive solution is subjected to reaction under heating, so that the polyamide-imide resin can be synthesized. As heating conditions, the temperature is set to be preferably from 0° C. to 200° C., both inclusive, and the time is set to be preferably from 1 hour to 24 hours, both inclusive.

In order to efficiently dissolve the polyamide-imide resin in the solvent, a number average molecular weight of the polyamide-imide resin is preferably from 10,000 to 40,000, both inclusive. This number average molecular weight is a value determined by gel permeation chromatography.

Insulating layer 3 may contain bismaleimide. Therefore, the liquid composition for forming insulating layer 3 may contain bismaleimide. This bismaleimide further improves the heat resistance of insulating layer 3. As the bismaleimide, insulating layer 3 contains, for example, one or more kinds of components selected from the group consisting of 4,4′-diphenylmethane bismaleimide, bisphenol A diphenylether bismaleimide, 3,3′-dimethyl-5,5′-diethyl-4,4′-diphenylmethane bismaleimide, and 1,6′-bismaleimide-(2,2,4-trimethyl)hexane.

The content of bismaleimide, with respect to 100% by mass of the total of the polyamide-imide resin and bismaleimide, is preferably from 3% by mass to 30% by mass, both inclusive. When the content of bismaleimide is 3% by mass or more, insulating layer 3 is provided with significantly high heat resistance. When the content of bismaleimide is 30% by mass or less, insulating layer 3 has good softness. The content of bismaleimide is more preferably from 3% by mass to 20% by mass, both inclusive.

The liquid composition may contain an epoxy compound, in place of bismaleimide or together with bismaleimide. The epoxy compound improves the heat resistance of insulating layer 3. Examples of the epoxy compound include multifunctional epoxy resins having a naphthalene skeleton. Examples of the multifunctional epoxy resin having a naphthalene skeleton include novolac epoxy resins, trifunctional epoxy resins, aralkyl epoxy resins, and cresol co-condensed epoxy resins. Other than these, examples of the multifunctional epoxy compound include bisphenol A epoxy resins, polyphenol epoxy resins, polyglycidylamine type epoxy resins, alcohol epoxy resins, alicyclic epoxy resins, and novolac epoxy resins having a phenol skeleton and a biphenyl skeleton.

The content of the epoxy compound, with respect to 100% by mass of the total of the polyamide-imide resin and the epoxy compound, is preferably from 3% by mass to 30% by mass, both inclusive. When the content of the epoxy compound is 3 parts by mass or more, the heat resistance of insulating layer 3 is significantly improved. Also, when the content of the epoxy compound is 30% by mass or less, insulating layer 3 has good softness. The content of the epoxy compound is more preferably from 3 parts by mass to 20% by mass, both inclusive.

Insulating layer 3 may contain an inorganic filler. Therefore, the liquid composition may contain an inorganic filler.

The inorganic filler contains, for example, silica.

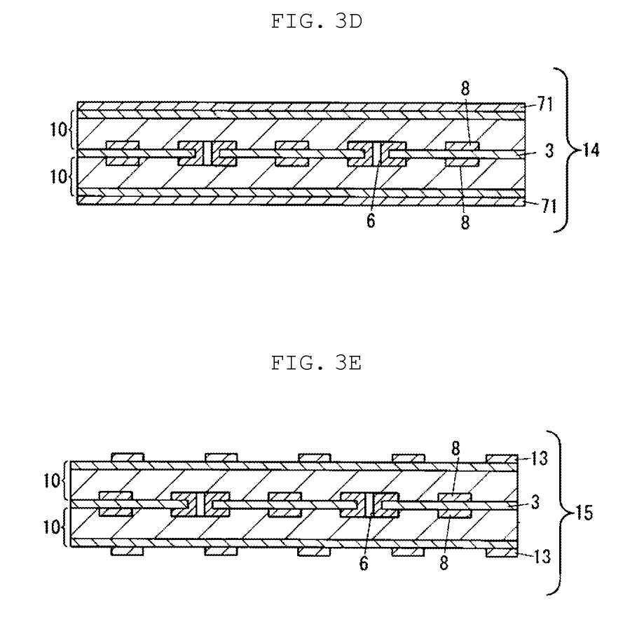

When the inorganic filler contains silica, it means that insulating layer 3 contains silica. In this case, silica can provide insulating layer 3 with high heat conductivity. Due to high heat conductivity, when a hole is formed in insulating layer 3 by laser processing, generation of resin residue on an inner surface of the hole, and formation of unevenness on an inner surface of the hole are suppressed. The hole is used for forming through hole 6 described below (refer to FIG. 3B). Also, a desmear liquid such as an alkali permanganic acid solution is used, so that formation of unevenness on an inner surface of the hole is suppressed even when a desmear treatment is applied to the inner surface of the hole. Therefore, when a plating treatment is applied to an inner surface of a hole for forming through hole 6, a plating layer is easily uniformly formed. By doing this, a stable conduction path is formed on an inner surface of through hole 8.

An average particle size of the silica is preferably from 5 nm to 200 nm, both inclusive. The silica has a maximum particle size of preferably 500 nm or less. In this ease, the silica suppresses inhibition of flexibility of insulating layer 3. The silica in insulating layer 3 is preferably from 2 phr to 20 phr, both inclusive. The average particle size and maximum particle size of the silica are determined by dynamic light scattering method. The silica is preferably spherical silica. The spherical silica improves a filling property of the silica in insulating layer 3.

The solvent used in the liquid composition contains, for example, one or more kinds of components selected from the group consisting of N-methyl-2-pyrrolidone, N,N-dimethylformamide, N,N-dimethylacetamide, 1,3-dimethyl-2-imidazolidinone, tetramethylurea, sulfolane, dimethyl sulfoxide, γ-butyrolactone, cyclohexanone, and cyclopentanone. Alternatively, the solvent can further contain one or more kinds of components selected from the group consisting of hydrocarbon-based organic solvents such as toluene and xylene, ether-based organic solvents such as diglyme, triglyme and tetrahydrofuran, and ketone-based organic solvents such as methyl ethyl ketone and methyl isobutyl ketone. Also, the solvent used in the synthesis of the polyamide-imide resin may be blended as it is to the liquid composition.

In order to provide the liquid composition with good application property and film formability, it is preferred to set the amount of the solvent in the liquid composition. It is particularly preferred to set the amount of the solvent such that a viscosity of the liquid composition is from 200 cP to 800 cP, both inclusive. The viscosity of the liquid composition is measured in an environment at 25° C. using, for example, a B-type viscometer.

The liquid composition may contain a proper additive in addition to the above components.

In the first method for manufacturing laminate board 1, a step after adjusting the liquid composition will be described.

As a method for applying the liquid composition to one surface of metal foil 41, comma coating, die coating, roll coating, gravure coating and the like may be used.

As a condition for heating the liquid composition on metal foil 41, the liquid composition is heated such that the maximum temperature during heating is 200° C. or more and less than 300° C. The maximum temperature is further preferably from 240° C. to 270° C., both inclusive. The heating time is preferably from 1 minute to 10 minutes, both inclusive.

When the liquid composition is heated, for example, the liquid composition is first primarily heated, and then secondarily heated at a temperature that is higher than that of the primary heating. The liquid composition is gradually heated using the above heating method, so that generation of bubbles on a surface layer of resin layer 5 can be suppressed in forming resin layer 5 from this liquid composition. As conditions for the primary heating, the heating temperature is preferably from 100° C. to 170° C., both inclusive, and the heating time is preferably from 1 minute to 10 minutes, both inclusive. As heating condition for the secondary heating, the heating temperature is preferably from 200° C. to 300° C., both inclusive, and is a temperature that is higher than the temperature of the primary heating. The heating time in the secondary heating is preferably from 1 minute to 10 minutes, both inclusive.

Metal foil 41, resin layer 5 and metal foil 42 may be pressed, during heating of resin layer 5, in a direction in which these foils and layer are laminated. The pressure during pressing is preferably from 2 MPa to 5 MPa, both inclusive. The heating time is preferably from 10 seconds to 20 minutes, both inclusive.

In the second method for manufacturing laminate board 1, a step after adjusting the liquid composition will be described.

As a method for applying the liquid composition to each one surface of metal foils 41, 42, the same method as the first method can be used. As conditions for heating the liquid composition on metal foils 41, 42, the same temperature condition and the same time condition as the heating method of the liquid composition in the first method can be used.

When laminated resin layers 51, 52 are heated, resin layers 51, 52 may be pressurized with metal foils 41, 42 in the same manner as in the first method. At this time, as heating conditions of resin layers 51, 52, the same temperature condition and pressure condition as the heating method of resin layer 5 in the first method can be used.

According to either the first method or the second method, insulating layer 3 is firmly bonded to metal layers 21, 22. Therefore, laminate board 1 including insulating layer 3 that is a single layer and is in direct contact with first metal layers 21, 22 is obtained.

A thickness of insulating layer 3 is preferably from 4 μm to 12 μm, both inclusive. Due to this thickness, insulating layer 3 has a good electrical insulation property and also can have good flexibility. Also, insulating layer 3 has a thickness of 12 μm or less, so that laminate board 1 can be provided with high electrical capacitance. In laminate board 1, insulating layer 3 is a single layer and contains the polyamide-imide resin, thus the thickness of insulating layer 3 can be easily made thin as described above.

A glass transition temperature of insulating layer 3 is preferably 300° C. or more. In this case, insulating layer 3 has significantly high heat resistance. A glass transition temperature of insulating layer 3 is more preferably from 300° C. to 350° C., both, inclusive. Also, an elastic modulus of insulating layer 3 at the glass transition temperature is preferably 0.1 GPa or more. In this case, insulating layer 3 has excellent flexibility. Also, in order to provide insulating layer 3 with excellent flexible property, the elastic modulus is more preferably from 0.1 GPa to 1.0 GPa, both inclusive. In laminate board 1, by appropriately adjusting the composition of insulating layer 3 within the range described above, it can be achieved that, a glass transition temperature of insulating layer 3 is between 300° C. and 350° C., and an elastic modulus of insulating layer 3 at the glass transition temperature is from 0.1 GPa to 1.0 GPa, both inclusive.

A surface roughness Rz of each, of a surface of metal layer 21 and a surface of metal layer 22, which are respectively contacting with insulating layer 3, namely ten-point average roughness Rz, is preferably from 0.5 μm to 3.0 μm, both inclusive. In order to achieve this, it is preferred that a surface roughness Rz of each surface of metal foils 41, 42 is from 0.5 μm to 3.0 μm, both inclusive. In this case, the excellent electrical insulation property of insulating layer 3 and excellent peel strength between metal layer 21 and insulating layer 3 are both, achieved. Here, the ten-point average roughness Rz is, in a profile curve, a sum of the average value of heights from the highest peak to the fifth peak and the average value of depths from the deepest, valley to the fifth valley. The profile curve is based on a standard length obtained by applying a phase compensation high-pass filter having a cut off value of λc. A phase compensation low-pass filter having a cut off value of λs is not applied to a method of obtaining the ten-point average roughness Rz. The profile curve is a roughness curve defined by old standard JIS B 0601:1994.

An electrical capacitance of laminate board 1 is preferably 0.2 nF/cm² or more. In this case, capacitance can be increased with a small area. Therefore, laminate board 1 is preferred especially for forming a substrate built-in type capacitor.

Laminate board 1 having high flexibility and high heat resistance, which is constituted as described above, is used for, for example, preparing a printed wiring board. In particular, laminate board 1 is preferably used for manufacturing a flexible printed wiring board.

A first embodiment of printed wiring board 15 produced by using laminate board 1 will be described with reference to FIG. 3A to FIG. 3E.

Each of metal layers 21, 22 of laminate board 1 illustrated in FIG. 3A is subjected to an etching treatment or the like, so that conductor wirings 8 are formed from metal layers 21, 22 as illustrated in FIG. 3B. Further, through hole 6 may be formed in insulating layer 3 by forming a hole in insulating layer 3 by laser processing or the like, and also plating an inner surface of this hole. By the above method, core material 9 including insulating layer 3 and conductor wirings 8 is obtained.

As illustrated in FIG. 3C, metal-clad substrates 7 are prepared. Each of metal-clad substrates 7 has a third metal layer (metal layer 71), first layer 72 disposed on metal layer 71, and second layer 73 disposed on a surface of first layer 72 opposite to a surface on which metal layer 72 is provided. Metal layer 71 is, for example, a copper foil. First layer 72 is made of, for example, an electrical insulating material having flexibility such as a polyimide resin, a poly amide imide resin, a liquid crystal polymer, a polyethylene terephthalate resin, or a polyethylene naphthalate resin. Second layer 73 is made of, for example, an electrical insulating material having thermosetting property such as an epoxy resin. In printed wiring board 15, two metal-clad substrates 7 are prepared.

Core material 9 is disposed between two metal-clad substrates 7. Then, second layers 73 in each of metal-clad substrates 7 are respectively laminated on conductor wirings 8 at both sides of core material 9. In this laminated state, two metal-clad substrates 7 and core material 9 are heated while being pressurized in a direction in which these materials are laminated. Accordingly, second layers 73 are first softened, thus a part of softened second layers 73 is filled between lines of conductor wirings 8. When through holes 6 are formed in insulating layer 3, a part of second layers 73 is also filled in through holes 6. Subsequently, second layers 73 are thermally cured. Accordingly, as illustrated in FIG. 3D, second insulating layers (insulating layers 10) constituted by cured products of first layers 72 and second layers 73 are formed.

When core material 9 and two metal-clad substrates 7 are laminated and integrated by the above procedure, laminated body 14 illustrated in FIG. 3D is obtained. In laminated body 14, conductor wirings 8, insulating layer 10 and metal layer 71 are laminated in this order, on each of both surfaces of insulating layer 3 in a thickness direction.

In preparation of laminated body 14, second layer 73 in metal-clad substrate 7 may be laminated only on one of conductor wirings 8 in core material 9. In this case, in laminated body 14, conductor wirings 8, insulating layer 10 and metal layer 71 are laminated in this order, on only one surface of insulating layer 3 in a thickness direction.

Third metal layer 71 that is an outermost layer of laminated body 14 is subjected to a treatment such as etching treatment so that second conductor wirings (conductor wirings 13) are formed as illustrated in FIG. 3E. Accordingly, a multilayer flexible printed wiring board is obtained as printed wiring board 15. In printed wiring board 15, conductor wirings 8, insulating layer 10 and conductor wiring 13 are laminated in this order, on each of both surfaces of insulating layer 3 in a thickness direction.

A plurality of metal-clad substrates 7 are sequentially laminated on one surface of core material 9, so that a flexible printed wiring board can be also further multilayered. By this method, a multilayer flexible printed wiring board can be produced.

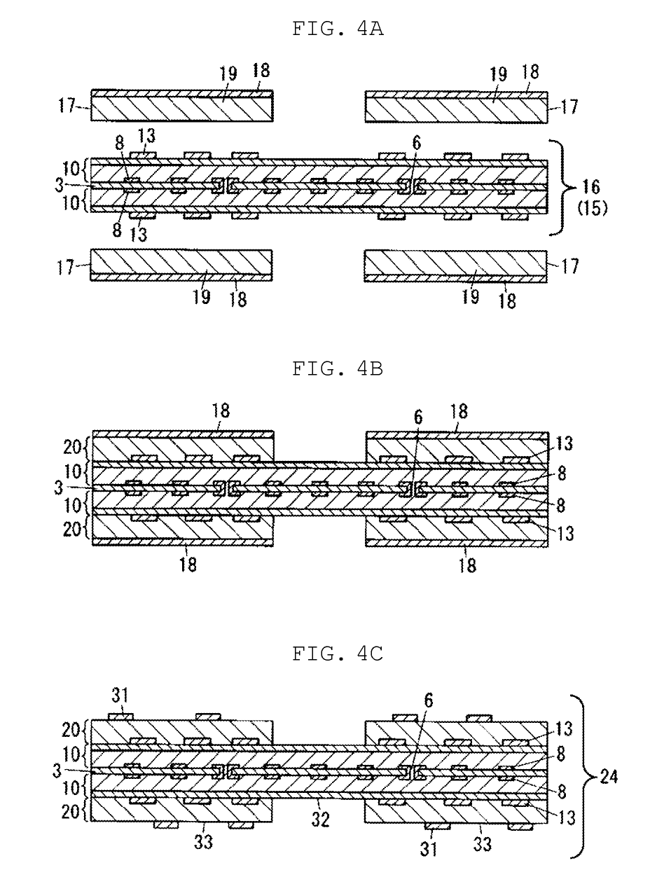

Next, flex-rigid printed wiring board 24 produced by using laminate board 1 will be described with reference to FIG. 4A to FIG. 4C. Hereinafter, flex-rigid printed wiring board 24 is referred as printed wiring board 24.

As illustrated in FIG. 4C, printed wiring board 24 includes a plurality of rigid parts 33, and flex, part 32 each connecting rigid parts 33. Rigid parts 33 can endure weights of components to be loaded. Rigid parts 33 have hardness and strength that can be fixed to a housing. Each of flex parts 32 is constituted by a part that is not multilayered in core material 18. Flex part 32 is a bendable and flexible part. For example, in a state that flex part, 32 is bent, printed wiring board 24 is housed in a housing of a small and light apparatus such as a portable electronic apparatus.

Printed wiring board 24 is produced, for example, by the following method.

Printed wiring board 15 illustrated in FIG. 3E is used as core material 16.

Then, rigid parts 33 is formed by multilayering core material 16 excluding a part that is to be flex part 32. The procedure for multilayering is not particularly limited, and a known procedure is used. For example, as illustrated in FIG. 4A, a build up method using resin sheets 17 each with a metal foil for multilayering is adopted. Hereinafter, resin sheet 17 with a metal foil is referred as resin sheet 17.

Resin sheet 17 includes metal foil 18, and semi-cured resin layer 19 laminated on one surface of metal foil 18. In the method for producing resin sheet 17, for example, first, a thermosetting resin composition such as an epoxy resin composition is applied to a mat surface of metal foil 18 such as copper foil. This thermosetting resin composition is heated and dried until the resin composition reaches a semi-cured state (B stage state). Due to this heating and drying, resin layer 19 is formed from the thermosetting resin composition. According to the above method, resin sheet 17 is prepared. A thickness of metal foil 18 is preferably from 6 μm to 18 μm, both inclusive. A thickness of resin layer 19 is preferably from 10 μm to 100 μm, both inclusive.

As illustrated in FIG. 4A, in each of a plurality of regions where rigid parts 33 in core material 18 are formed, resin layers 19 of resin sheets 17 are laminated on both surfaces of these regions. When heat-press molding is performed in this state, resin layers 19 bond to core material 18. Further, resin layers 19 are cured, and third insulating layers (insulating layers 20) are formed as illustrated in FIG. 4B. As molding conditions, for example, the pressure is from 1 MPa to 3 MPa, both inclusive, and the temperature is from 160° C. to 200° C., both inclusive.

Metal foil 18 is subjected to an etching treatment or the like as illustrated in FIG. 4C, so that third conductor wirings (conductor wirings 31) are formed. Accordingly, rigid parts 33 are formed, and flex part 32 is formed between adjacent rigid parts 33. In rigid parts 33, a through hole, a via hole or the like may be formed as necessary. Rigid parts 33 may be further multilayered by build up method or the like.

### EXAMPLES

### Example 1

The following compounds are blended to obtain a mixture having a polymer concentration of 15% by mass. 192 g of trimellitic anhydride manufactured by Nacalai Tesque, Inc. is blended to this mixture. Further, 250.8 g of 4,4′-diisocyanato-3,3′-dimethylbiphenyl is blended. Also, 8.7 g of 2,4-diisocyanatotoluene is blended. Then, 1 g of diazabicycloundecene manufactured by SairApro Lid. is blended. Moreover, 2558.5 g of N,N-dimethylacetamide (DMAC) manufactured by Nacalai Tesque, Inc. is blended. The temperature of the mixture is raised up to 100° C. over 1 hour by heating. Subsequently, the temperature of the mixture is maintained at 100° C. for 6 hours to advance the reaction in the mixture.

Subsequently, 1.4 g of bismaleimide and 163.9 g of DMAC are added to 300 g of the reactant, so that the polymer concentration of the mixture is adjusted to 10% by mass. Then, the mixture is cooled to room temperature. By this method, a liquid composition in which the polyamide-imide resin and bismaleimide are dissolved is prepared. This liquid composition is yellowish brown transparent. Thus, it is confirmed that poly amide imide and bismaleimide are dissolved in the liquid composition.

As a first metal foil, a copper foil is prepared. The copper foil has a thickness of 12 μm. The copper foil has a surface with an Rz of 1 μm. The liquid composition is applied, with a comma coater, onto the surface with an Rz of 1 μm in this first metal foil. Subsequently, this liquid composition is primarily heated and further secondarily heated. As conditions for the primary heating, the temperature is 200° C., and the time is for 4 minutes. As conditions for the secondary heating, the temperature is 250° C., and the time is for 10 minutes. Accordingly, a first resin layer with a thickness of 2 μm is formed on the first metal foil.

As a second metal foil, the same copper foil as the first metal foil is prepared. A second resin layer with a thickness of 2 μm is formed on this second metal foil by the same method as the method for preparing the first resin layer.

In a state that the first resin layer and the second resin layer are laminated, the first metal foil, the first resin layer, the second resin layer and the second metal foil are heated while being pressed. The pressure is 4 MPa, the temperature is 330° C., and the time is for 10 minutes.

According to the above method, a double-sided metal-clad laminate board, which includes a first metal layer, an insulating layer and a second metal layer, is obtained. The insulating layer appearing in a cross section of this double-sided metal-clad laminate board has a minimum thickness of 4 μm.

### Examples 2 to 13

The blend molar ratio of trimellitic anhydride, 4,4′-diisocyanato-3,3′-dimethylbiphenyl and 2,4-diisocyanatotoluene for synthesizing the poly amide-imide resin, the composition of the liquid composition, and the heating temperatures in the primary heating and the secondary heating, in Example 1, are changed to those shown in Table 1 and Table 2 shown below.

The result, of measuring the minimum thickness of the insulating layer appearing in the cross section of obtained double-sided metal-clad laminate board 1 is also shown in Tables 1, 2 shown below.

Here, “bismaleimide 1” in the tables is 4,4′-diphenylmethane bismaleimide, and item number BMI-1000 manufactured by Darwa Kasei Industry Co., Ltd. is used. “Bismaleimide 2” is bisphenol A diphenylether bismaleimide, and item number BMI-4000 manufactured by Daiwa Kasei Industry Co., Ltd. is used.

### Example 14

As a first metal foil, the same copper foil as in Example 1 is prepared. On the copper foil, a liquid composition with the same composition as in Example 1 is applied onto a surface with an Rz of 1 μm in this first metal foil with a comma coater. Subsequently, primary heating and secondary heating are performed on this liquid composition. As conditions for the primary heating, the temperature is 200° C., and the time is for 4 minutes. As conditions for the secondary heating, the temperature is 250° C., and the time is for 10 minutes. Accordingly, a first resin layer with a thickness of 10 μm is formed on the first metal foil.

As a second metal foil, the same copper foil as the first metal foil is prepared. A surface with an Rz of 1 nm in this second metal foil is laminated on the first resin layer. In the laminated state, the first metal foil, the first resin layer and the second metal foil are heated while being pressed. The pressure is 4 MPa, the temperature is 330° C., and the time is for 10 minutes.

According to the above method, a double-sided metal-clad laminate board, which includes a first metal layer, an insulating layer and a second metal layer, is obtained. The insulating layer appearing in a cross section of this double-sided metal-clad laminate board has a minimum thickness of 9 μm,

### Comparative Example 1

In Example 1, the conditions for the primary heating for forming the first resin layer are changed to 180° C. for 4 minutes, and the secondary heating is not performed. As the conditions for the primary heating for forming the second resin layer, the temperature is also 180° C., and the time is also for 4 minutes. The secondary heating is not performed.

As a result, swelling is observed in a metal layer of the resulting double-sided metal-clad laminate board. Therefore, as to Comparative Example 1, evaluation tests described below are not performed.

### Comparative Example 2

In Example 1, as the conditions for the primary heating for forming the first resin layer, the temperature is 200° C., and the time is for 4 minutes. As the conditions for the secondary heating, the temperature is 350° C., and the time is for 10 minutes. As the conditions for the primary heating for forming the second resin layer, the temperature is 200° C., and the time is for 4 minutes. As the conditions for the secondary heating, the temperature is 350° C., and the time is for 10 minutes.

Then, the first resin layer and the second resin layer are laminated in the same manner as in Example 1. In the laminated state, the first metal foil, the first resin layer, the second resin layer and the second metal foil are heated while being pressed. The pressure is 4 MPa, the temperature is 330° C., and the time is for 10 minutes. However, even when heating, the first resin layer and the second resin layer are not bonded, and an insulating layer is not formed. Therefore, as to Comparative Example 2, evaluation tests described below are not performed.

### Comparative Example 3

A thermoplastic polyimide varnish is diluted twice with N-methyl-2-pyrrolidone, so that a liquid composition is obtained. As the thermoplastic polyimide varnish, item number PN-20 manufactured by New Japan Chemical Co., Ltd. is used.

The same copper foil as the first metal foil in Example 1 is prepared as a first metal foil or a second metal foil. The liquid composition is applied onto each of the first metal foil and the second metal foil by using a comma coater. Subsequently, primary heating and secondary heating are performed on this liquid composition. As conditions for the primary heating, the temperature is 200° C., and the time is for 2 minutes. As conditions for the secondary heating, the temperature is 200° C., and the time is for 15 minutes. Accordingly, a first resin layer with a thickness of 4 μm and a second resin layer with a thickness of 4 μm are formed on the first metal foil and the second metal foil, respectively.

The first resin layer and the second resin layer are each laminated on both surfaces of a polyimide film with a thickness of 12 μm. In the laminated state, the first metal foil, second metal foil, the first resin layer, second resin layer, and the polyimide film are heated while being pressed. The pressure is 4 MPa, the temperature is 330° C., and the time is for 10 minutes. As the polyimide film, trade name APICAL NPI manufactured by Kaneka Corporation is used.

According to the above method, a double-sided metal-clad laminate board, which includes a first metal layer, an insulating layer and a second metal layer, is obtained. The insulating layer appearing in a cross section of this double-sided metal-clad laminate board has a minimum thickness of 20 μm.

### Comparative Example 4

In Comparative Example 3, the conditions for the primary heating to form the first resin layer and the second resin layer are changed to 200° C. and 2 minutes, and the conditions for the secondary heating are changed to 220° C. and 15 minutes.

Accordingly, a double-sided metal-clad laminate board, which includes a first metal layer, an insulating layer and a second metal layer, is obtained. The insulating layer appearing in a cross section of this double-sided metal-clad laminate board has a minimum thickness of 20 μm.

### [Evaluation Tests]

### (1) Adhesion Evaluation

A peeling strength is measured when a copper foil in a double-sided metal-clad laminate board is peeled in the 90° direction.

### (2) Solder Heat Resistance

A double-sided metal-clad laminate board is immersed in a soldering bath at 288° C., and then the time until abnormal appearance such as swelling or peeling is generated on the double-sided metal-clad laminate board is measured. It is evaluated as “C” when the time is less than 1 minute, it is evaluated as “B” when the time is 1 minute and more and less than 2 minutes, and it is evaluated as “A” when the time is 2 minutes or more.

### (3) Electrical Capacitance Measurement

According to JIS C6471 7.5 (corresponding international standard- IEC 249-1 (1982)), a double-sided metal-clad laminate board is subjected to an etching treatment to prepare a sample, and the electrical capacitance of this sample is measured.

### (4) Elastic Modulus Evaluation

Copper foils on both surfaces of a double-sided metal-clad laminate board are removed by etching. Then, the glass transition temperature of the insulating layer, and the elastic modulus of the insulating layer at the glass transition temperature are measured. In the measurement, a dynamic viscoelasticity measuring device manufactured by SII NanoTechnology Inc. is used. The peak of tan δ obtained by the dynamic viscoelasticity measuring device is used as a glass transition temperature.

TABLE 1

| | | Examples | | | | | | | | |
|---|---|---|---|---|---|---|---|---|---|---|
| | | 1 | 2 | 3 | 4 | 5 | 6 | 7 | 8 | 9 |
| Raw material | Trimellitic anhydride | 50 | 50 | 50 | 50 | 50 | 50 | 50 | 50 | 50 |
| composition (mol %) | 4,4′-Diisocyanato- | 47.5 | 40 | 32.5 | 40 | 40 | 40 | 50 | 25 | 40 |
| in synthesis of | 3,3′-dimethylbiphenyl | | | | | | | | | |
| polyamide-imide resin | 2,4-Diisocyanatotoluene | 2.5 | 10 | 17.5 | 10 | 10 | 10 | 0 | 25 | 10 |
| Ratio (mol %) of constituent unit | | 95 | 80 | 65 | 80 | 80 | 80 | 100 | 50 | 80 |
| X in polyamide-imide resin | | | | | | | | | | |
| Ratio (mol %) of constituent unit | | 5 | 20 | 35 | 20 | 20 | 20 | 0 | 50 | 20 |
| Y in polyamide-imide resin | | | | | | | | | | |
| Composition of | Polyamide-imide resin | 97 | 90 | 70 | 97 | 85 | 70 | 90 | 90 | 100 |
| liquid composition | Bismaleimide 1 | 3 | 10 | 30 | 0 | 0 | 0 | 10 | 10 | 0 |
| (parts by mass) | Bismaleimide 2 | 0 | 0 | 0 | 3 | 15 | 30 | 0 | 0 | 0 |
| Maximum temperature of primary heating (° C.) | | 200 | 200 | 200 | 200 | 200 | 200 | 200 | 200 | 200 |
| Maximum temperature of secondary heating (° C.) | | 250 | 270 | 290 | 200 | 250 | 270 | 270 | 270 | 250 |
| Thickness of insulating layer (μm) | | 4 | 8 | 12 | 4 | 8 | 12 | 8 | 8 | 8 |
| Evaluation | Adhesion (N/mm) | 1.1 | 1.1 | 1.1 | 1.1 | 1.1 | 1.1 | 0.7 | 0.8 | 1.0 |
| | Solder heat resistance 300° C. | A | A | A | A | A | A | A | B | B |
| | Electrical capacitance (nF/cm²) | 0.72 | 0.31 | 0.23 | 0.69 | 0.34 | 0.22 | 0.32 | 0.31 | 0.34 |
| | Glass transition temperature (° C.) | 327 | 336 | 340 | 327 | 338 | 339 | 328 | 335 | 325 |
| | Elastic modulus at glass | 0.2 | 0.8 | 0.6 | 0.2 | 0.2 | 0.3 | 0.7 | 0.5 | 0.09 |
| | transition temperature (GPa) | | | | | | | | | |

TABLE 2

| | | Examples | | | | | Comparative Examples | | | |
|---|---|---|---|---|---|---|---|---|---|---|
| | | 10 | 11 | 12 | 13 | 14 | 1 | 2 | 3 | 4 |
| Raw material | Trimellitic anhydride | 50 | 50 | 50 | 50 | 50 | 50 | 50 | — | — |
| composition (mol %) | 4,4′-Diisocyanato- | 40 | 40 | 40 | 40 | 47.5 | 47.5 | 47.5 | — | — |
| in synthesis of | 3,3′-dimethylbiphenyl | | | | | | | | | |
| polyamide-imide resin | 2,4-Diisocyanatotoluene | 10 | 10 | 10 | 10 | 2.5 | 2.5 | 2.5 | — | — |
| Ratio (mol %) of constituent unit | | 80 | 80 | 80 | 80 | 95 | 95 | 95 | — | — |
| X in polyamide-imide resin | | | | | | | | | | |
| Ratio (mol %) of constituent unit | | 20 | 20 | 20 | 20 | 5 | 5 | 5 | — | — |
| Y in polyamide-imide resin | | | | | | | | | | |
| Composition of | Polyamide-imide resin | 60 | 85 | 85 | 85 | 97 | 97 | 97 | (Thermoplastic | |
| liquid composition | Bismaleimide 1 | 40 | 0 | 0 | 0 | 3 | 3 | 3 | polyamide- | |
| (parts by mass) | Bismaleimide 2 | 0 | 15 | 15 | 15 | 0 | 0 | 0 | imide solution) | |
| Maximum temperature of primary heating (° C.) | | 200 | 180 | 200 | 200 | 200 | 180 | 200 | 200 | 200 |
| Maximum temperature of secondary heating (° C.) | | 250 | 180 | 350 | 250 | 250 | — | 350 | 200 | 220 |
| Thickness of insulating layer (μm) | | 8 | 8 | 8 | 26 | 9 | — | — | 20 | 20 |
| Evaluation | Adhesion (N/mm) | 0.7 | 0.5 | 0.3 | 1.1 | 1.0 | — | — | 0.1 | 0.1 |
| | Solder heat resistance 300° C. | C | C | B | A | A | — | — | C | C |
| | Electrical capacitance (nF/cm²) | 0.29 | 0.31 | 0.30 | 0.11 | 0.30 | — | — | 0.15 | 0.14 |
| | Glass transition temperature. (° C.) | 340 | 338 | 340 | 338 | 327 | — | — | 270 | 270 |
| | Elastic modulus at glass | 1.1 | 0.1 | 1.1 | 0.2 | 0.2 | — | — | — | — |
| | transition temperature (GPa) | | | | | | | | | |

### INDUSTRIAL APPLICABILITY

It is useful since a double-sided metal-clad laminate board that includes an insulating layer having high flexibility and high heat resistance is obtained.

### REFERENCE MARKS IN THE DRAWINGS

1: Double-sided metal-clad laminate board (laminate board)

13: Second conductor wiring (conductor wiring)

14: Laminated body

15: Flexible printed wiring board (printed wiring board)

21: First metal layer (metal layer)

22: Second metal layer (metal layer)

24: Flex-rigid printed wiring board (printed wiring board)

3: Insulating layer

10: Second insulating layer (insulating layer)

31: Third conductor wiring (conductor wiring)

32: Flex part

33: Rigid part

41: First metal foil (metal foil)

42: Second metal foil (metal foil)

5: Resin layer

51: First resin layer (resin layer)

52: Second resin layer (resin layer)

6: Through hole

7: Metal-clad substrate

71: Third metal layer (metal layer)

72: First layer

73: Second layer

8: Conductor wiring

9, 18: Core material

17: Resin sheet

18: Metal foil

19: Resin layer

20: Third insulating layer (insulating layer)

1. A double-sided metal-clad laminate board comprising:
a first, metal layer;
a second metal layer; and
an insulating layer intervening between the first metal layer and the second metal layer, and being in direct contact with the first metal layer and the second metal layer, wherein
the insulating layer is a single layer containing a polyamide-imide resin having at least one of a first constituent unit represented by structural formula (1) and a second constituent unit represented by structural formula (2):

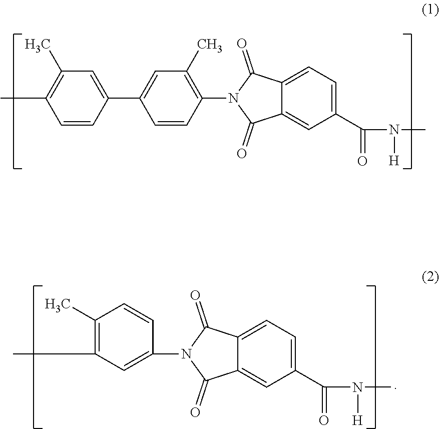

2. The double-sided metal-clad laminate board according to claim 1, wherein:
the polyamide-imide resin has the first constituent unit and the second constituent unit, and
a proportion of the second constituent unit to a total content of the first constituent unit and the second constituent unit is from 5% by mol to 35% by mol, both inclusive.

3. The double-sided metal-clad laminate board according to claim 1, wherein the insulating layer further contains bismaleimide.

4. The double-sided metal-clad laminate board according to claim 3, wherein a content of the bismaleimide with respect to 100% by mass of a total of the polyamide-imide resin and the bismaleimide is from 3% by mass to 30% by mass, both inclusive.

5. The double-sided metal-clad laminate board according to claim 3, wherein the bismaleimide contains at least one kind selected from the group consisting of 4,4′-diphenylmethane bismaleimide, bisphenol A diphenylether bismaleimide, 3,3′-dimethyl-5,5′-diethyl-4,4′-diphenylmethane bismaleimide, and 1,6′-bismaleimide-(2,2,4-trimethyl)hexane.

6. The double-sided metal-clad laminate board according to claim 1, wherein a glass transition temperature of the insulating layer is from 300° C. to 350° C., both inclusive, and an elastic modulus of the insulating layer at the glass transition temperature is from 0.1 GPa to 1.0 GPa, both inclusive.

7. The double-sided metal-clad laminate board according to claim 1, wherein the double-sided metal-clad laminate board has an electrical capacitance of 0.2 nF/cm² or more.

8. A method for manufacturing a double-sided metal-clad laminate board, the method comprising steps of:
applying a liquid composition containing a polyamide-imide resin and a solvent onto a first metal foil;
forming a resin layer on the first metal foil by heating the liquid composition such that a maximum temperature is 200° C. or more and less than 300° C.; and
forming an insulating layer by heating the resin layer, in a state that a second metal foil is laminated on the resin layer formed on the first metal foil, such that a maximum temperature is from 300° C. to 350° C., both inclusive; wherein
the polyamide-imide resin has at least one of a first constituent unit represented by structural formula (1) and a second constituent unit represented by structural formula (2):

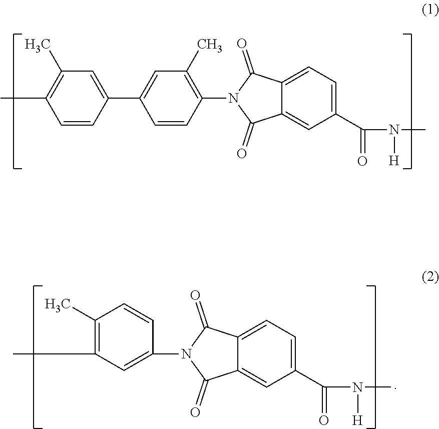

9. A method for manufacturing a double-sided metal-clad laminate board, the method comprising steps of
applying a liquid composition containing a polyamide-imide resin and a solvent onto a first metal foil,
forming a first resin layer on the first metal foil by heating the liquid composition on the first metal foil such that a maximum temperature is 200° C. or more and less than 300° C.;
applying a liquid composition containing a polyamide-imide resin and a solvent onto a second metal foil;
forming a second resin layer on the second metal foil by heating the liquid composition on the second metal foil such that a maximum temperature is 200° C. or more and less than 300° C.; and
forming an insulating layer by heating the first resin layer and the second resin layer, in a state that the first resin layer and the second resin layer are laminated, such that a maximum temperature is from 300° C. to 350° C., both inclusive, wherein
the polyamide-imide resin has at least one of a first constituent unit represented by structural formula (1) and a second constituent unit represented by structural formula (2): [chemical structure]
